(19) United States
(12) Patent Application Publication
(10) Pub. No.: US 2024/0019785 A1
(43) Pub. Date: Jan. 18, 2024

(54) FACET SYSTEM AND LITHOGRAPHY APPARATUS

(71) Applicant: Carl Zeiss SMT GmbH, Oberkochen (DE)

(72) Inventor: Ralf Ameling, Aalen (DE)

(21) Appl. No.: 18/468,270

(22) Filed: Sep. 15, 2023

Related U.S. Application Data
(63) Continuation of application No. PCT/EP22/57388, filed on Mar. 21, 2022.

(30) Foreign Application Priority Data
Mar. 22, 2021 (DE) 102021202768.7

(51) Int. Cl. G03F 7/00; G02B 26/08

(52) U.S. Cl. CPC G03F 7/70116; G02B 26/0858

(57) ABSTRACT

A facet system for a lithography apparatus comprises: a facet element with an optically effective surface; a first piezoactuator arrangement for tilting the facet element about a first spatial direction; and a second piezoactuator arrangement for tilting the facet element about a second spatial direction oriented at right angles to the first spatial direction. The first piezoactuator arrangement and the second piezoactuator arrangement are arranged in a common plane which is spanned by the first spatial direction and the second spatial direction.

### CROSS-REFERENCE TO RELATED APPLICATIONS

The present application is a continuation of, and claims benefit under 35 USC 120 to, in-ternational application PCT/EP2022/057388, filed Mar. 21, 2022, which claims benefit under 35 USC 119 of German Application No 10 2021 202 768.7, filed Mar. 22, 2021. The entire disclosure of each these applications is incorporated by reference herein.

### FIELD

The present summary relates to a facet system for a lithography apparatus, and to a lithography apparatus comprising such a facet system.

### BACKGROUND

Microlithography is used for producing microstructured components, such as for example integrated circuits. The microlithography process is performed using a lithography apparatus, which has an illumination system and a projection system. The image of a mask (reticle) illuminated via the illumination system is in this case projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses (extreme ultraviolet, EUV) that use light with a wavelength in the range of 0.1 nm to 30 nm, in particular 13.5 nm, are currently under development. In the case of such EUV lithography apparatuses, because of the typically high absorption of light of this wavelength by most materials, reflective optical units, that is to say mirrors, are used instead of—as previously—refractive optical units, that is to say lens elements. The mirrors usually operate either with almost normal incidence or with grazing incidence.

The illumination system generally comprises, in particular, a field facet mirror and a pupil facet mirror. The field facet mirror and the pupil facet mirror can be in the form of so-called facet mirrors, wherein such facet mirrors often have hundreds of facets in each case. The facets of the field facet mirror are also referred to as “field facets” and the facets of the pupil facet mirror as “pupil facets”. A plurality of pupil facets can be assigned to one field facet. In order to obtain a good illumination in conjunction with a high numerical aperture, it can be desirable for the one field facet to be switchable between the pupil facets assigned to it.

### SUMMARY

The present summary seeks to provide an improved facet system.

In a first aspect, a facet system for a lithography apparatus is proposed. The facet system comprises a facet element with an optically effective surface, a first piezoactuator arrangement for tilting the facet element about a first spatial direction, and a second piezoactuator arrangement for tilting the facet element about a second spatial direction oriented at right angles to the first spatial direction, wherein the first piezoactuator arrangement and the second piezoactuator arrangement are arranged in a common plane which is spanned by the first spatial direction and the second spatial direction.

As a result of the first piezoactuator arrangement and the second piezoactuator arrangement being provided, it is possible to tilt the facet element both about the first spatial direction and about the second spatial direction. By suitably actuating the first piezoactuator arrangement and the second piezoactuator arrangement, it is possible to obtain any combined tilt about the first spatial direction and the second spatial direction. This allows the facet element to be switched into any number of different tilt positions.

The facet system can be a field facet system or a pupil facet system. The facet system can also be part of a specular reflector. The facet element can be a field facet element or a pupil facet element. The facet system can be part of a beam-shaping and illumination system of the lithography apparatus. For example, the facet system is part of a facet mirror, such as a field facet mirror. Such a facet mirror can comprise a multiplicity of such facet systems arranged in chequerboard-like fashion or in the shape of a pattern. That is to say, the facet systems can be arranged next to one another in rows and below one another in columns. Such a field facet mirror may comprise any number of facet systems. By way of example, the field facet mirror may comprise several hundred thousand facet systems. Each facet element can be tilted by itself into a plurality of different tilt positions.

A coordinate system having the first spatial direction or x-direction, the second spatial direction or y-direction and a third spatial direction or z-direction is assigned to the facet system. The spatial directions are positioned at right angles to one another. The third spatial direction can be oriented at right angles to the optically effective surface. The first spatial direction and the second spatial direction can be oriented parallel to the optically effective surface.

The facet element can be produced from a mirror substrate or substrate. The substrate may comprise silicon in particular. The optically effective surface can be provided on the front side at the facet element, that is to say facing away from the piezoactuator arrangements. The optically effective surface reflects light. The optically effective surface can be a mirror surface. The optically effective surface can be produced with the aid of a coating applied to the facet element. The facet element itself can be opaque to light. The optically effective surface is suitable for reflecting working light or light, such as EUV radiation. However, this does not preclude at least some of the light being absorbed by the facet element, as a result of which heat is introduced into the latter.

The first piezoactuator arrangement can serve to tilt the facet element about the first spatial direction which can be oriented parallel to the optically effective surface. Accordingly, the second piezoactuator arrangement can serve to tilt the facet element about the second spatial direction which can be oriented parallel to the optically effective surface and at right angles to the first spatial direction. The optically effective surface can be flat. However, the optically effective surface can also be curved. By way of example, the optically effective surface can be cylindrical or toroidal.

The piezoactuator arrangements can also be referred to as piezoelement arrangements or piezo actuating element arrangements. In the present case, a “piezoactuator” or “piezoelement” should be understood to mean a component which exploits the so-called piezo effect in order to carry out a mechanical movement as a result of the application of a voltage. The terms “piezoactuator” and “piezoelement” can be interchanged as desired. Each piezoactuator arrangement may comprise a plurality of piezoactuators. Two piezoactuators can be assigned to each piezoactuator arrangement. The piezoactuators are so-called bending transducers or can be referred to as such.

In a plan view, that is to say in a viewing direction at right angles to the optically effective surface, the facet element can completely conceal both the first piezoactuator arrangement and the second piezoactuator arrangement. That is to say that light incident on the facet system can be incident exclusively on the optically effective surface and not on further components of the facet system such as the piezoactuator arrangements, for example. Consequently, it is possible to obtain a high degree of fill of the facet element or the optically effective surface.

The first piezoactuator arrangement can be suitable for pivoting or tilting the facet element only about the first spatial direction or about an axis oriented parallel to the first spatial direction. Accordingly, the second piezoactuator arrangement can be suitable for tilting the facet element only about the second spatial direction or about an axis oriented parallel to the second spatial direction. Any number of tilt states or tilt positions of the facet element can be set with the aid of the first piezoactuator arrangement and the second piezoactuator arrangement.

The facet system can comprise a control unit suitable for actuating the piezoactuator arrangements or piezoactuators assigned to the piezoactuator arrangements. A voltage can be applied to the respective piezoactuator for actuating purposes. By applying the voltage, the respective piezoactuator can deform in order to tilt the facet element. In this case, the respective piezoactuator can be converted from a non-deformed or non-deflected state to a deformed or deflected state. Any number of intermediate states can be provided between the non-deflected state and the deflected state. That is to say, the piezoactuator can be deformed or deflected continuously between the non-deflected state and the deflected state.

According to an embodiment, the first piezoactuator arrangement and/or the second piezoactuator arrangement are configured to perform a stroke movement of the facet element in a third spatial direction oriented at right angles to the optically effective surface.

This can result in a further degree of freedom. The facet element consequently can have at least three degrees of freedom, specifically a rotational degree of freedom about the first spatial direction, a rotational degree of freedom about the second spatial direction and a translational degree of freedom in the third spatial direction. To allow the facet element to carry out the stroke movement, the piezoactuators can be assigned to the respective piezoactuator arrangement are actuated simultaneously and also deflected to the same extent such that the stroke movement in the third spatial direction arises. A combined stroke and tilting movement of the facet element may also be carried out. Should the optically effective surface be curved, the third spatial direction can be oriented at right angles to an apex of the optically effective surface, for example.

The first piezoactuator arrangement and the second piezoactuator arrangement can be arranged in a common plane which is spanned by the first spatial direction and the second spatial direction.

The common plane can also be arranged parallel to a plane spanned by the first spatial direction and the second spatial direction. By way of example, bottom sides or top sides of the piezoactuators of the piezoactuator arrangements are all arranged in the common plane. As soon as one of the piezoactuators is actuated or has a current applied thereto, the piezoactuator can be deformed out of the common plane, as a result of which the facet element can be tilted.

According to an embodiment, the first piezoactuator arrangement comprises at least two piezoactuators, which are configured to selectively tilt the facet element about the first spatial direction in two oppositely oriented tilt movements.

The tilt movements may also be referred to as tilt directions. By way of example, the tilt movements can be oriented clockwise and anticlockwise about the first spatial direction. By way of example, a first tilt movement is oriented anticlockwise and a second tilt movement is oriented clockwise. By way of example, the facet element can consequently be tilted through a tilt angle of 100 mrad, for example. If both piezoactuators of the first piezoactuator arrangement are actuated simultaneously and deflected to the same extent, the facet element can carry out the aforementioned stroke movement. As mentioned previously, a combination of the tilt movement and the stroke movement may also be carried out.

According to an embodiment, the second piezoactuator arrangement comprises at least two piezoactuators, which are configured to selectively tilt the facet element about the second spatial direction in two oppositely oriented tilt movements.

The tilt movements can be oriented clockwise and anticlockwise about the second spatial direction. By way of example, provision is made of a third tilt movement with clockwise orientation and a fourth tilt movement with anticlockwise orientation. The first tilt movement and the second tilt movement can be oriented at right angles to the third tilt movement and the fourth tilt movement. As mentioned previously, the tilt movements may also be referred to as tilt directions.

According to an embodiment, the piezoactuators of the first piezoactuator arrangement and the piezoactuators of the second piezoactuator arrangement are arranged in a row.

In particular, this can mean that all piezoactuators are placed one behind the other. The piezoactuators of the first piezoactuator arrangement and the piezoactuators of the second piezoactuator arrangement can be constructed identically. In particular, the piezoactuators can be what are known as piezoelectric bending transducers, which do not change their length but their curvature when a current is applied thereto.

According to an embodiment, the piezoactuators of the first piezoactuator arrangement and the piezoactuators of the second piezoactuator arrangement are arranged alternately.

In particular, this can mean that a piezoactuator of the first piezoactuator arrangement is in each case arranged between two piezoactuators of the second piezoactuator arrangement, and vice versa. A first piezoactuator, a second piezoactuator, a third piezoactuator and a fourth piezoactuator can be provided, the second piezoactuator being arranged between the first piezoactuator and the third piezoactuator. In particular, the third piezoactuator can be placed between the second piezoactuator and the fourth piezoactuator.

According to an embodiment, the piezoactuators of the first piezoactuator arrangement are arranged parallel to one another and at a distance from one another, with the piezoactuators of the second piezoactuator arrangement likewise being arranged parallel to one another and at a distance from one another.

In particular, the piezoactuators of the first piezoactuator arrangement can be arranged at a distance from one another and parallel to one another when viewed in the second spatial direction. Accordingly, the piezoactuators of the second piezoactuator arrangement can be arranged parallel to one another and at a distance from one another when viewed in the first spatial direction. In particular, the piezoactuators can be in the form of elongate and bar-shaped or strip-shaped components. The piezoactuators have the greatest geometric extent along a principal direction of extent or longitudinal direction. The piezoactuators of the first piezoactuator arrangement can be placed in such a way that, in particular, these extend in the first spatial direction with their principal direction of extent. Accordingly, the piezoactuators of the second piezoactuator arrangement can be placed in such a way that, in particular, these extend in the second spatial direction with their principal direction of extent.

According to an embodiment, the piezoactuators of the first piezoactuator arrangement and the piezoactuators of the second piezoactuator arrangement are arranged at right angles to one another.

Accordingly, this can yield a helical or spiral arrangement of the piezoactuators. In particular, as mentioned previously, provision can be made of a first piezoactuator, a second piezoactuator, a third piezoactuator and a fourth piezoactuator. In this case, the second piezoactuator can be arranged at right angles to the first piezoactuator. In turn, the third piezoactuator can be placed at right angles to the second piezoactuator. The fourth piezoactuator can be placed at right angles to the third piezoactuator. The first piezoactuator and the third piezoactuator can be assigned to the first piezoactuator arrangement. Accordingly, the second piezoactuator and the fourth piezoactuator can be assigned to the second piezoactuator arrangement. In the present case, “at right angles” should be understood to mean that the above-described principal directions of extent of the piezoactuators are placed at right angles to one another. In the present case, “at right angles” should be further understood to mean an angle of 90°±10°, such as of 90°±5°, as an example of 90°±1°, as another example exactly 90°.

According to an embodiment, the facet system further comprises a first piezoactuator, a second piezoactuator, a third piezoactuator and a fourth piezoactuator, with the first piezoactuator and the third piezoactuator being assigned to the first piezoactuator arrangement and the second piezoactuator and the fourth piezoactuator being assigned to the second piezoactuator arrangement.

That is to say, the first piezoactuator arrangement comprises the first piezoactuator and the third piezoactuator. Accordingly, the second piezoactuator arrangement comprises the second piezoactuator and the fourth piezoactuator. The number of piezoactuators can be arbitrary. In particular, however, exactly four piezoactuators are provided.

According to an embodiment, the facet system further comprises a substrate, with only the first piezoactuator being connected to the substrate.

The substrate may also be referred to as main body of the facet system. The substrate can be made of silicon. However, the substrate may also comprise copper, such as a copper alloy, an iron-nickel alloy, such as Invar, for example, silicon or some other suitable material. In the present case, “only” the first piezoactuator being connected to the substrate means that the second to fourth piezoactuators do not have a fixed connection to the substrate. In particular, gaps may be provided in each case between the second to fourth piezoactuator and the substrate. The piezoactuator arrangements are arranged between the substrate and the facet element.

According to an embodiment, the first piezoactuator is only connected to the substrate and the second piezoactuator, the second piezoactuator only being connected to the first piezoactuator and the third piezoactuator, the third piezoactuator only being connected to the second piezoactuator and the fourth piezoactuator, and the fourth piezoactuator only being connected to the third piezoactuator and the facet element.

A bar-shaped connection section with a linking site can be provided on the fourth piezoactuator, the facet element being fastened thereto. By way of example, the facet element may be cohesively connected to the linking site. In cohesive connections, the connection partners are held together by atomic or molecular forces. Cohesive connections are non-releasable connections that can be separated only by destruction of the connection means and/or the connection partners. A cohesive connection may be implemented by adhesive bonding or soldering, for example. By way of example, the facet element is connected to the linking site with the aid of any bonding method.

According to an embodiment, the facet element is square in the plan view.

In the present case, the “plan view” should be understood to mean a viewing direction at right angles to the optically effective surface. However, the facet element may also have any other desired geometry in the plan view. By way of example, the facet element is elongate and rectangular, round, hexagonal or elongate and curved in arcuate fashion.

According to an embodiment, the facet system is an integral component.

In the present case, “integral” or “one part” should be understood to mean that the facet system is not constructed from a plurality of separable components but instead forms a common or integral component. By way of example, the facet system can be realized via microelectromechanical production methods (microelectromechanical systems, MEMS). In this case, a three-dimensional microstructure constructed from a plurality of base layers can be realized using different coating methods, microstructuring and etching techniques, and bonding methods. By way of example, the microstructure can be made of silicon. By way of example, the piezoactuators may be based on piezoceramics, such as lead zirconate titanate (PZT).

According to an embodiment, sensors are integrated into the facet system.

The sensors may comprise any number of sensors, in particular capacitive sensors.

Further, a lithography apparatus comprising such a facet system is proposed.

The lithography apparatus can comprise a multiplicity of such facet systems. The lithography apparatus can be an EUV lithography apparatus or a DUV lithography apparatus. EUV stands for “extreme ultraviolet” and denotes a wavelength of the working light of between 0.1 nm and 30 nm. DUV stands for “deep ultraviolet” and denotes a wavelength of the working light of between 30 nm and 250 nm.

“A(n); one” in the present case should not necessarily be understood as restrictive to exactly one element. Rather, a plurality of elements, such as, for example, two, three or more, can also be provided. Any other numeral used here, too, should not be understood to the effect that there is a restriction to exactly the stated number of elements. Rather, numerical deviations upwards and downwards are possible, unless indicated to the contrary.

The embodiments and features described for the facet system apply correspondingly to the proposed lithography apparatus, and vice versa.

Further possible implementations of the summary also comprise not explicitly mentioned combinations of any features or embodiments that are described above or below with respect to the exemplary embodiments. In this case, a person skilled in the art will also add individual aspects as improvements or supplementations to the respective basic form of the summary.

Further configurations and aspects of the summary are the subject matter of the dependent claims and also of the exemplary embodiments of the summary described below. In the text that follows, the summary will be explained in more detail on the basis of preferred embodiments with reference to the accompanying figures.

### BRIEF DESCRIPTION OF THE DRAWINGS

FIG. 1A shows a schematic view of an embodiment of an EUV lithography apparatus;

FIG. 1B shows a schematic view of an embodiment of a DUV lithography apparatus;

FIG. 2 shows a schematic view of one embodiment of an optical arrangement for the lithography apparatus in accordance with FIG. 1A or FIG. 1B;

FIG. 3 shows a schematic view of a further embodiment of an optical arrangement for the lithography apparatus in accordance with FIG. 1A or FIG. 1B;

FIG. 4 shows a schematic plan view of one embodiment of a field facet mirror for the optical arrangement in accordance with FIG. 2;

FIG. 5 shows the detail view V in accordance with FIG. 4;

FIG. 6 shows a further schematic view of the optical arrangement in accordance with FIG. 2;

FIG. 7 shows a schematic plan view of an embodiment of an optical system for the optical arrangement in accordance with FIG. 2 and for the optical arrangement in accordance with FIG. 3;

FIG. 8 shows a schematic sectional view of the optical system in accordance with the sectional line IIX-IIX in FIG. 7;

FIG. 9 shows a schematic sectional view of the optical system in accordance with the sectional line IX-IX in FIG. 7;

FIG. 10 shows a schematic sectional view of an embodiment of a piezoactuator for the optical system in accordance with FIG. 7;

FIG. 11 shows a schematic perspective view of a further embodiment of an optical system for the optical arrangement in accordance with FIG. 2 and for the optical arrangement in accordance with FIG. 3;

FIG. 12 shows a further schematic perspective view of the optical system in accordance with FIG. 11;

FIG. 13 shows a schematic perspective view of a further embodiment of an optical system for the optical arrangement in accordance with FIG. 2 and for the optical arrangement in accordance with FIG. 3; and

FIG. 14 shows a further schematic perspective view of the optical system in accordance with FIG. 13.

### DETAILED DESCRIPTION

Unless indicated to the contrary, elements that are the same or functionally the same have been provided with the same reference signs in the figures. It should also be noted that the illustrations in the figures are not necessarily true to scale.

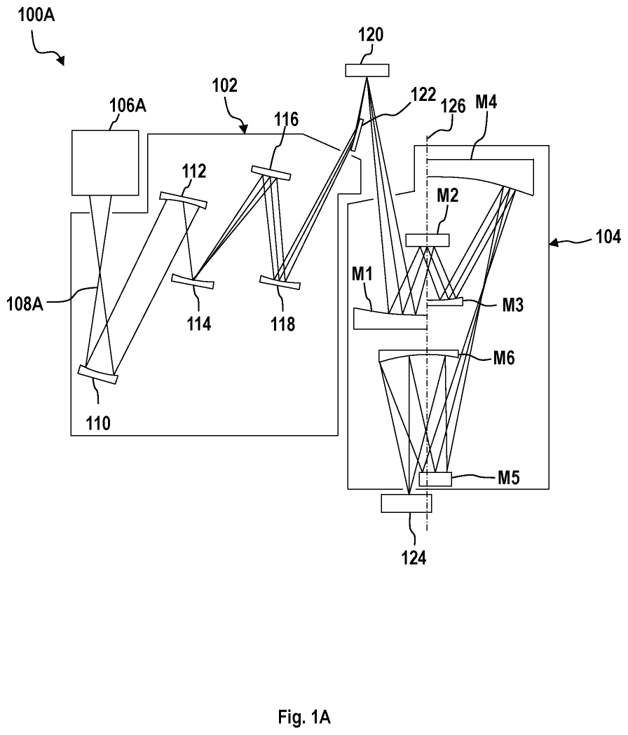

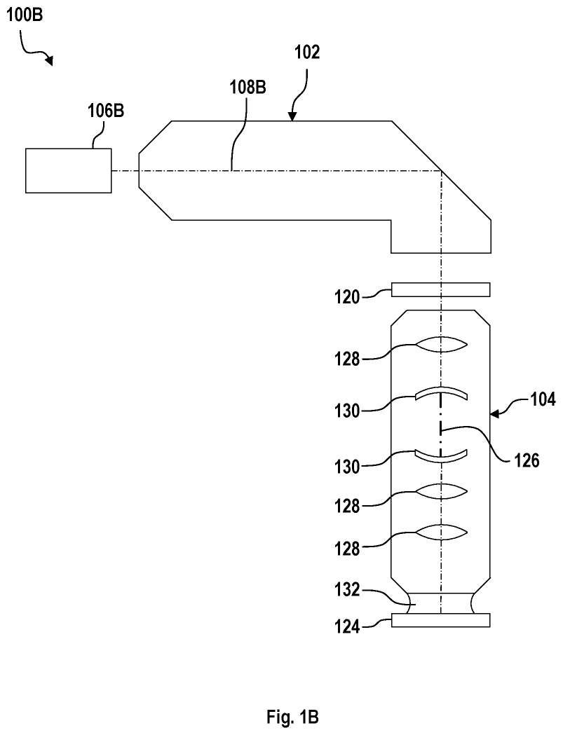

FIG. 1A shows a schematic view of an EUV lithography apparatus 100A comprising a beam-shaping and illumination system 102 and a projection system 104. In this case, EUV stands for “extreme ultraviolet” and denotes a wavelength of the working light of between 0.1 nm and 30 nm. The beam-shaping and illumination system 102 and the projection system 104 are respectively provided in a vacuum housing (not shown), each vacuum housing being evacuated with the aid of an evacuation device (not shown). The vacuum housings are surrounded by a machine room (not shown), in which drive apparatuses for mechanically moving or setting optical elements are provided.

Furthermore, electrical controllers and the like may also be provided in the machine room.

The EUV lithography apparatus 100A has an EUV light source 106A. A plasma source (or a synchrotron), which emits radiation 108A in the EUV range (extreme ultraviolet range), that is to say for example in the wavelength range of 5 nm to 20 nm, can for example be provided as the EUV light source 106A. In the beam-shaping and illumination system 102, the EUV radiation 108A is focused and the desired operating wavelength is filtered out from the EUV radiation 108A. The EUV radiation 108A generated by the EUV light source 106A has a relatively low transmissivity through air, for which reason the beam-guiding spaces in the beam-shaping and illumination system 102 and in the projection system 104 are evacuated.

The beam-shaping and illumination system 102 illustrated in FIG. 1A has five mirrors 110, 112, 114, 116, 118. After passing through the beam-shaping and illumination system 102, the EUV radiation 108A is guided onto a photomask (also known as a reticle) 120. The photomask 120 is likewise in the form of a reflective optical element and may be arranged outside the systems 102, 104. Furthermore, the EUV radiation 108A may be directed onto the photomask 120 via a mirror 122. The photomask 120 has a structure which is imaged onto a wafer 124 or the like in a reduced fashion via the projection system 104.

The projection system 104 (also referred to as a projection lens) has six mirrors M1 to M6 for imaging the photomask 120 onto the wafer 124. In this case, individual mirrors M1 to M6 of the projection system 104 may be arranged symmetrically in relation to an optical axis 126 of the projection system 104. It should be noted that the number of mirrors M1 to M6 of the EUV lithography apparatus 100A is not restricted to the number shown. A greater or lesser number of mirrors M1 to M6 may also be provided.

Furthermore, the mirrors M1 to M6 are generally curved on their front sides for beam shaping.

FIG. 1B shows a schematic view of a DUV lithography apparatus 100B, which comprises a beam-shaping and illumination system 102 and a projection system 104. In this case, DUV stands for “deep ultraviolet” and denotes a wavelength of the working light of between 30 nm and 250 nm. As has already been described with reference to FIG. 1A, the beam-shaping and illumination system 102 and the projection system 104 can be surrounded by a machine room with corresponding drive devices.

The DUV lithography apparatus 100B has a DUV light source 106B. By way of example, an ArF excimer laser that emits radiation 108B in the DUV range at 193 nm, for example, can be provided as the DUV light source 106B.

The beam-shaping and illumination system 102 illustrated in FIG. 1B guides the DUV radiation 108B onto a photomask 120. The photomask 120 is formed as a transmissive optical element and may be arranged outside the systems 102, 104. The photomask 120 has a structure which is imaged onto a wafer 124 or the like in a reduced fashion via the projection system 104.

The projection system 104 has a plurality of lens elements 128 and/or mirrors 130 for imaging the photomask 120 onto the wafer 124. In this case, individual lens elements 128 and/or mirrors 130 of the projection system 104 may be arranged symmetrically in relation to an optical axis 126 of the projection system 104. It should be noted that the number of lens elements 128 and mirrors 130 of the DUV lithography apparatus 100B is not restricted to the number shown. A greater or lesser number of lens elements 128 and/or mirrors 130 can also be provided. Furthermore, the mirrors 130 are generally curved on their front sides for beam shaping.

An air gap between the last lens element 128 and the wafer 124 can be replaced by a liquid medium 132 having a refractive index >1. The liquid medium 132 may be for example high-purity water. Such a setup is also referred to as immersion lithography and has an increased photolithographic resolution. The medium 132 can also be referred to as an immersion liquid.

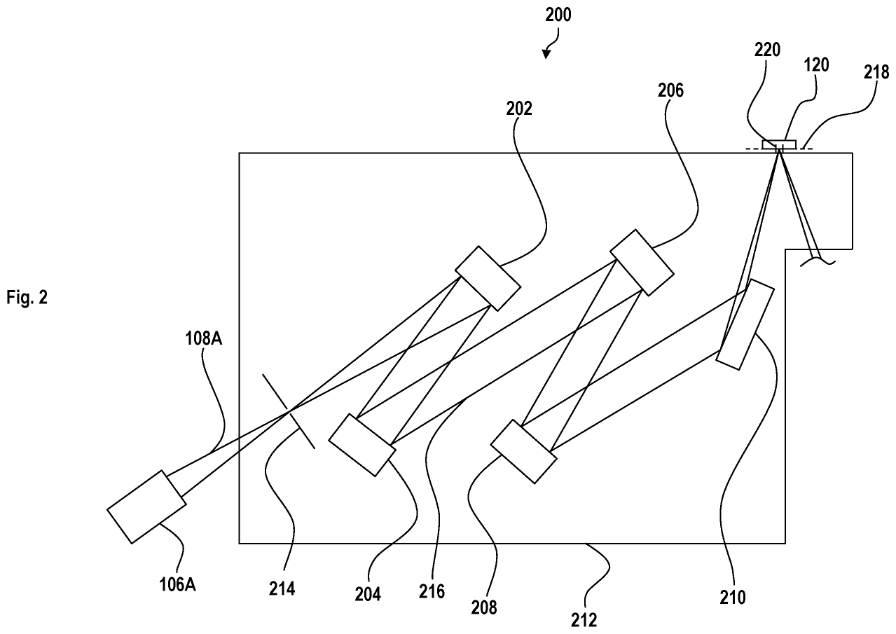

FIG. 2 shows a schematic view of an embodiment of an optical arrangement 200. The optical arrangement 200 is a beam-shaping and illumination system 102, in particular a beam-shaping and illumination system 102 of an EUV lithography apparatus 100A. The optical arrangement 200 can therefore also be designated as a beam-shaping and illumination system and the beam-shaping and illumination system 102 can be designated as an optical arrangement. The optical arrangement 200 can be disposed upstream of a projection system 104 as explained above.

However, the optical arrangement 200 can also be part of a DUV lithography apparatus 100B. However, it is assumed below that the optical arrangement 200 is part of an EUV lithography apparatus 100A. Besides the optical arrangement 200, FIG. 2 also shows an EUV light source 106A as explained above, which emits EUV radiation 108A, and a photomask 120. The EUV light source 106A can be part of the optical arrangement 200.

The optical arrangement 200 comprises a plurality of mirrors 202, 204, 206, 208. Furthermore, an optional deflection mirror 210 can be provided. The deflection mirror 210 is operated with grazing incidence and can therefore also be called a grazing incidence mirror. The deflection mirror 210 can correspond to the mirror 122 shown in FIG. 1A. The mirrors 202, 204, 206, 208 can correspond to the mirrors 110, 112, 114, 116, 118 shown in FIG. 1A. In particular, the mirror 202 corresponds to the mirror 110, and the mirror 204 corresponds to the mirror 112.

The mirror 202 is a so-called facet mirror, in particular a field facet mirror, of the optical arrangement 200. The mirror 204 is also a facet mirror, in particular a pupil facet mirror, of the optical arrangement 200. The mirror 202 reflects the EUV radiation 108A to the mirror 204. At least one of the mirrors 206, 208 can be a condenser mirror of the optical arrangement 200. The number of mirrors 202, 204, 206, 208 is arbitrary. By way of example, it is possible to provide, as shown in FIG. 1A, five mirrors 202, 204, 206, 208, namely the mirrors 110, 112, 114, 116, 118, or, as shown in FIG. 2, four mirrors 202, 204, 206, 208. However, at least three mirrors 202, 204, 206, 208 can be provided, namely a field facet mirror, a pupil facet mirror, and a condenser mirror.

The mirrors 202, 204, 206, 208 are arranged within a housing 212. The housing 212 can be subjected to a vacuum during operation, in particular during exposure operation, of the optical arrangement 200. That is to say that the mirrors 202, 204, 206, 208 are arranged in a vacuum.

During operation of the optical arrangement 200, the EUV light source 106A emits EUV radiation 108A. By way of example, a tin plasma can be produced for this purpose. In order to produce the tin plasma, a tin body, for example a tin bead or a tin droplet, can be bombarded with a laser pulse. The tin plasma emits EUV radiation 108A, which is collected with the aid of a collector, for example an ellipsoidal mirror, of the EUV light source 106A and is sent in the direction of the optical arrangement 200. The collector focuses the EUV radiation 108A at an intermediate focus 214. The intermediate focus 214 can also be designated as an intermediate focal plane or lies in an intermediate focal plane.

Upon passing through the optical arrangement 200, the EUV radiation 108A is reflected by the mirrors 202, 204, 206, 208 and also the deflection mirror 210. Not all mirrors 202, 204, 206, 208 are used in this case. The deflection mirror 210, in particular, is dispensable. A beam path of the EUV radiation 108A is denoted by the reference sign 216. The photomask 120 is arranged in an object plane 218 of the optical arrangement 200. An object field 220 is positioned in the object plane 218.

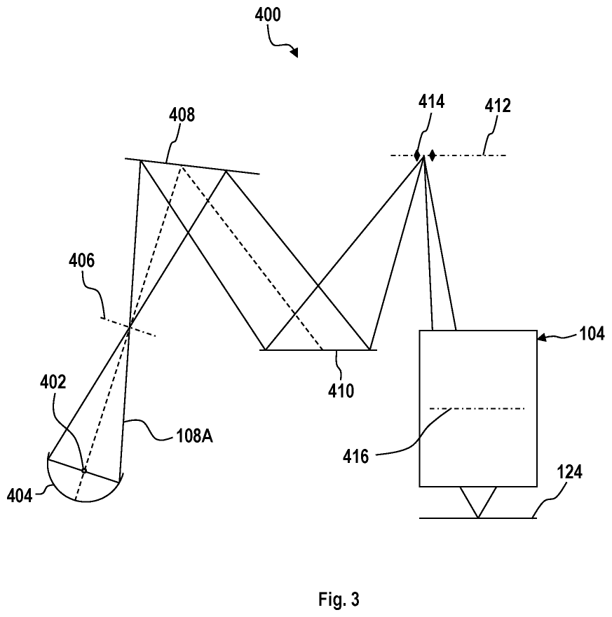

FIG. 3 shows a schematic view of a further embodiment of an optical arrangement 400. The optical arrangement 400—like the optical arrangement 200—is a beam-shaping and illumination system 102, in particular a beam-shaping and illumination system 102 of an EUV lithography apparatus 100A. The optical arrangement 400 can therefore also be designated as a beam-shaping and illumination system and the beam-shaping and illumination system 102 can be designated as an optical arrangement.

However, the optical arrangement 400 can also be part of a DUV lithography apparatus 100B. However, it is assumed below that the optical arrangement 400 is part of an EUV lithography apparatus 100A.

EUV radiation 108A emanating from a radiation source 402 is focused by a collector 404. Downstream of the collector 404, the EUV radiation 108A propagates through an intermediate focal plane 406 before being incident on a beam-shaping facet mirror 408 serving for the targeted illumination of a specular reflector 410. The specular reflector 410 is a mirror and may therefore also be referred to as a mirror. Using the beam-shaping facet mirror 408 and the specular reflector 410, the EUV radiation 108A is shaped such that the EUV radiation 108A completely illuminates an object field 414 in an object plane 412, a predefined, for example homogeneously illuminated, circularly bounded pupil illumination distribution, that is to say a corresponding illumination setting, emerging in a pupil plane 416 of the projection system 104, the pupil plane being disposed downstream of a reticle.

A reflection surface of the specular reflector 410 is subdivided into individual mirrors. Depending on the desired illumination properties, these individual mirrors of the specular reflector 410 are grouped to form individual mirror groups, that is to say to form facets of the specular reflector 410. Each individual-mirror group forms an illumination channel, which in each case by itself does not completely illuminate a reticle field. Only the sum of all the illumination channels results in a complete and homogeneous illumination of the reticle field. Both the individual mirrors of the specular reflector 410 and the facets of the beam-shaping facet mirror 408 can be tiltable by an actuator system, such that different field and pupil illuminations are settable.

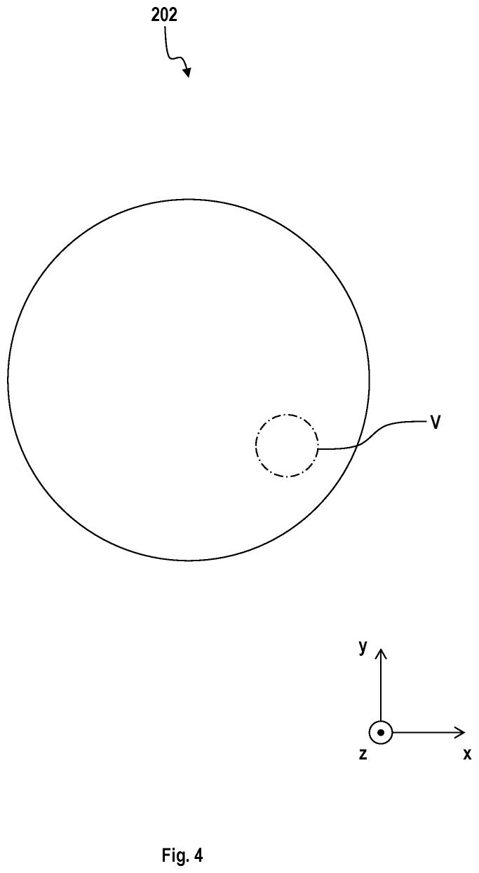

FIG. 4 shows a schematic plan view of one embodiment of a mirror 202 as explained above, which mirror is in the form of a facet mirror, in particular a field facet mirror. The mirrors 204, 408 and the specular reflector 410 may also be in the form of a facet mirror. However, only the mirror 202 is discussed below. However, all explanations relating to the mirror 202 are also applicable to the mirrors 204, 408, and to the specular reflector 410.

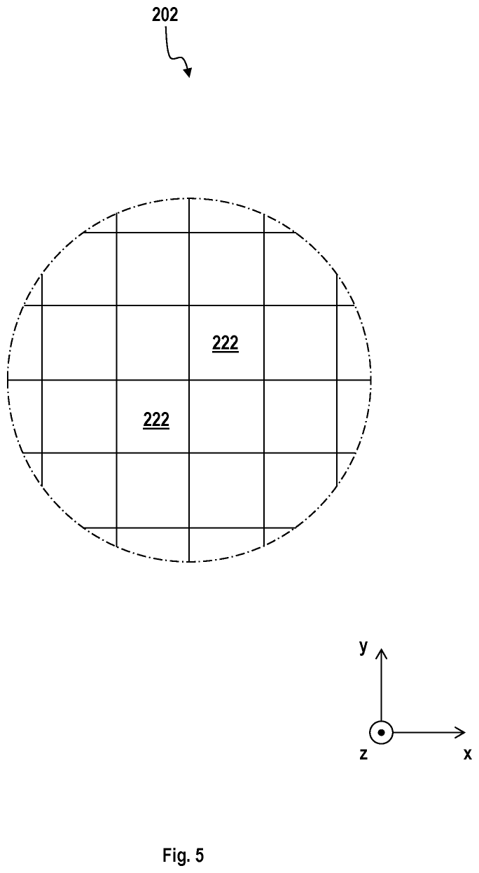

FIG. 5 shows the detail view IV in accordance with FIG. 4. Reference is made below to FIGS. 4 and 5 simultaneously. The facet mirror or field facet mirror is therefore designated hereinafter by the reference sign 202. A coordinate system having a first spatial direction or x-direction x, a second spatial direction or y-direction y and a third spatial direction or z-direction z is assigned to the field facet mirror 202.

The field facet mirror 202 comprises a multiplicity of facets 222, only two of which are provided with a reference sign in FIG. 5. The facets 222 are arranged in the form of a pattern, in the form of a grid or in chequerboard-like fashion. In particular, this means that the facets 222 are arranged next to one another in the form of rows and above one another in the form of columns. The facets 222 can be arranged in so-called bricks. Each brick may have 25×25 such facets 222. A distance of 40 to 50 μm can be provided between the facets 222 in a brick. A distance of 100 μm can be provided between the individual bricks.

The facets 222 are field facets, in particular, and are also designated as such hereinafter. By way of example, the field facet mirror 202 may comprise several hundred thousand field facets 222. Each field facet 222 can be individually tiltable. In the case where the facets 222 are assigned to the mirror 204, they may also be designated as pupil facets.

In the plan view according to FIGS. 4 and 5, the field facets 222 can be polygonal, for example quadrilateral. In particular, the field facets 222 can be square, as shown in FIG. 5. Should the field facets 222 be square, they may have an edge length of 1 mm, for example. However, the field facets 222 can also be round or hexagonal. In principle, the geometry of the field facets 222 is as desired. By way of example, the field facets 222 can also have an elongate rectangular geometry. The field facets 222 can also be curved in the plan view, in particular curved in arcuate fashion.

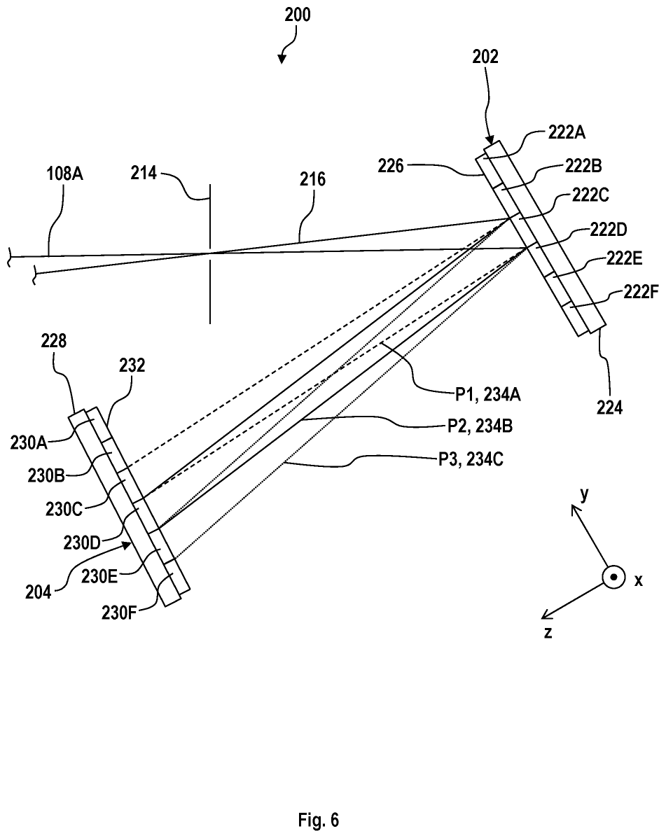

FIG. 6 shows a significantly enlarged excerpt from the optical arrangement 200 shown in FIG. 2. The optical arrangement 200 comprises the EUV light source 106A (not shown), which emits EUV radiation 108A, the intermediate focus 214, the field facet mirror 202 and also the mirror 204 in the form of a pupil facet mirror. The mirror 204 is designated hereinafter as a pupil facet mirror. The mirrors 206, 208, the deflection mirror 210 and the housing 212 are not shown in FIG. 6. The pupil facet mirror 204 is arranged at least approximately in an entrance pupil plane of the projection system 104 or a conjugate plane with respect thereto.

The intermediate focus 214 is an aperture stop of the EUV light source 106A. For the sake of simplicity, the description hereinafter does not draw a distinction between the aperture stop for producing the intermediate focus 214 and the actual intermediate focus, that is to say the opening in the aperture stop.

The field facet mirror 202 comprises a carrier body or main body 224, which—as mentioned above—carries a multiplicity of field facets 222A, 222B, 222C, 222D, 222E, 222F. The field facets 222A, 222B, 222C, 222D, 222E, 222F can have an identical form, but can also differ from one another, in particular in the shape of their boundary and/or a curvature of a respective optically effective surface 226. The optically effective surface 226 is a mirror surface. The optically effective surface 226 is plane. However, the optically effective surface 226 can also be curved.

The optically effective surface 226 serves to reflect the EUV radiation 108A in the direction towards the pupil facet mirror 204. In FIG. 6, only the optically effective surface 226 of the field facet 222A is provided with a reference sign. However, the field facets 222B, 222C, 222D, 222E, 222F likewise have such optically effective surfaces 226. The optically effective surface 226 can be designated as a field facet surface.

Only the field facet 222C is discussed below. However, all explanations concerning the field facet 222C also apply to the field facets 222A, 222B, 222D, 222E, 222F. Accordingly, only that part of the EUV radiation 108A which impinges on the field facet 222C is illustrated. However, the entire field facet mirror 202 is illuminated with the aid of the EUV light source 106A.

The pupil facet mirror 204 comprises a carrier body or main body 228, which carries a multiplicity of pupil facets 230A, 230B, 230C, 230D, 230E, 230F. Each of the pupil facets 230A, 230B, 230C, 230D, 230E, 230F has an optically effective surface 232, in particular a mirror surface. In FIG. 6, only the optically effective surface 232 of the pupil facet 230A is provided with a reference sign. The optically effective surface 232 is suitable for reflecting EUV radiation 108A. The optically effective surface 232 can be designated as a pupil facet surface.

For switching over between different pupils, the field facet 222C can be switched over between different pupil facets 230A, 230B, 230C, 230D, 230E, 230F. In particular, for this purpose, the pupil facets 230C, 230D, 230E are assigned to the field facet 222C. This involves tilting the field facet 222C. This tilting is implemented mechanically, for example through up to 100 mrad.

The field facet 222C— as mentioned above—is tiltable with the aid of an actuator (not illustrated) or a plurality of actuators between a plurality of positions or tilt positions P1, P2, P3. In a first tilt position P1, the field facet 222C images the intermediate focus 214 onto the pupil facet 230C with an imaging light beam 234A (illustrated by dashed lines). In a second tilt position P2, the field facet 222C images the intermediate focus 214 onto the pupil facet 230D with an imaging light beam 234B (illustrated by solid lines). In a third tilt position P3, the field facet 222C images the intermediate focus 214 onto the pupil facet 230E with an imaging light beam 234C (illustrated by dotted lines). The respective pupil facet 230C, 230D, 230E images the field facet 222C onto the photomask 120 (not illustrated here) or in proximity thereto.

To be able to bring the field facet 222C into the different tilt positions P1, P2, P3, it is desirable to be able to tilt the field facet 222C about two spatial directions, specifically the x-direction x and the y-direction y, in a plane spanned by the x-direction x and y-direction y. The aforementioned assignment of the field facet 222C to the pupil facets 230C, 230D, 230E should not be construed as mandatory. The assignment may differ depending on the illumination setting. The pupil facets 230C, 230D, 230E may also be tiltable. At the same time, it is desirable to be able to dissipate the high thermal load arising due to the EUV radiation 108A. A further desired property lies in high positioning accuracy of the field facet 222C and, connected therewith, a low sensitivity to disturbances such as temperature variations, for example.

To attain a fill factor of the field facet 222C that is as high as possible, it is desirable to arrange the entire actuator system, sensor system and further mechanical elements below the optically effective surface 226. To be able to realize the drive elements, sensor elements and mechanical elements of the field facet 222C using the conventional technologies for producing microelectromechanical systems (MEMS), a layer-like structure of the field facet 222C may be chosen.

For typical demands for use in EUV lithography apparatuses 100A, previous solutions, for example building on a capacitive actuator system, in this case place high demands on process technology. This applies in particular to high aspect ratios of the structures to be produced. Therefore, a design in which the actuator system, sensor system and mechanics for operating the field facet 222C can be produced using comparatively easy and few process steps is desirable.

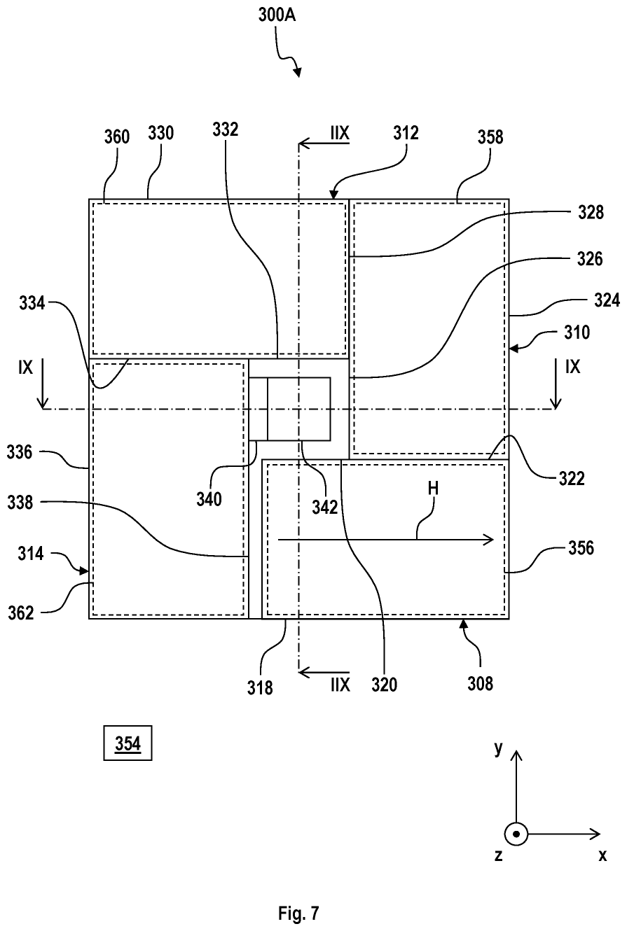

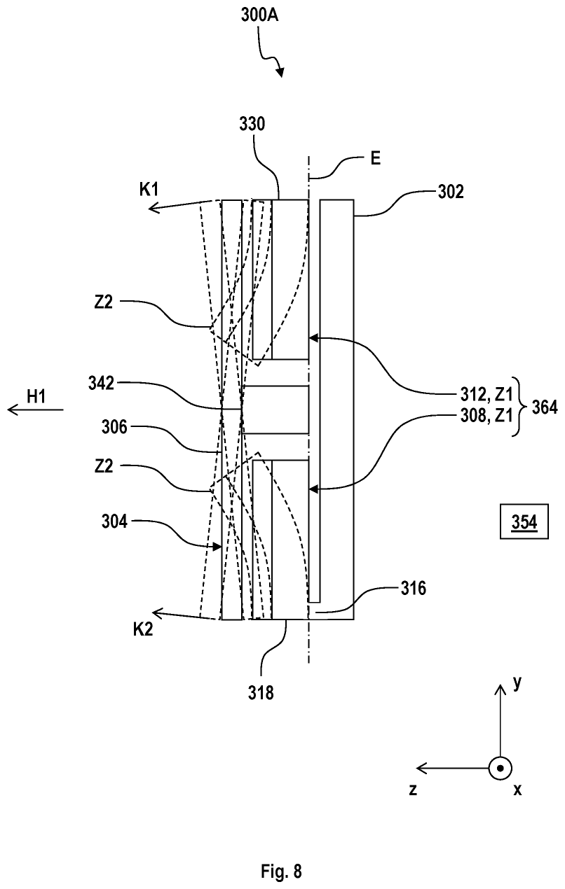

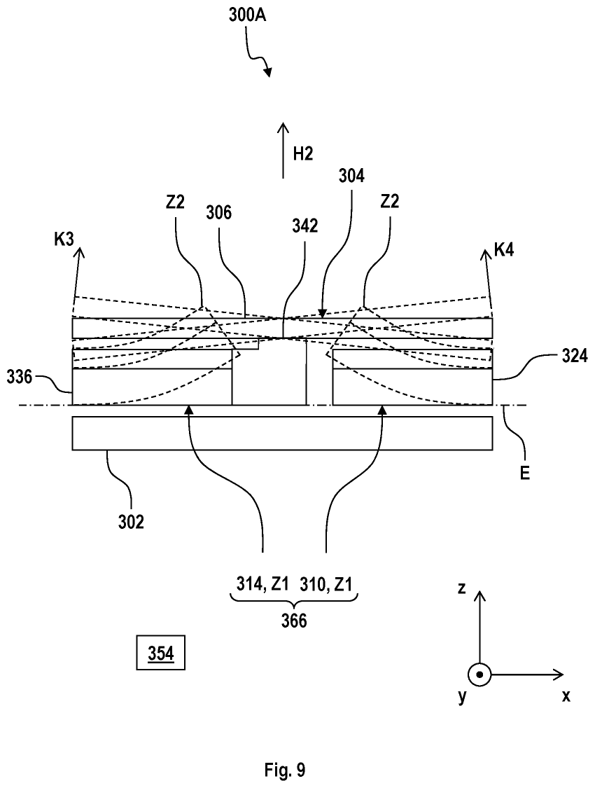

FIG. 7 shows a schematic view of one embodiment of an optical system 300A. FIG. 8 shows a schematic sectional view of the optical system 300A in accordance with the sectional line IIX-IIX in FIG. 7. FIG. 9 shows a further schematic sectional view of the optical system 300A in accordance with the sectional line IX-IX in FIG. 7. Reference is made below to FIGS. 7 to 9 simultaneously.

The optical system 300A is part of an optical arrangement 200, 400 as explained above. In particular, the optical arrangement 200, 400 can comprise a multiplicity of such optical systems 300A. The optical system 300A is, in particular, also part of a field facet mirror 202, pupil facet mirror 204, facet mirror 408 or specular reflector 410 as explained above. However, only the field facet mirror 202 is discussed below. However, all explanations relating to the field facet mirror 202 are accordingly applicable to the pupil facet mirror 204, to the facet mirror 408, or to the specular reflector 410.

The optical system 300A is a field facet 222A, 222B, 222C, 222D, 222E, 222F as explained above. The optical system 300A can therefore also be designated as a field facet, facet system, field facet system or field facet apparatus. The optical system 300A can be a facet system, in particular a field facet system. However, the optical system 300A can also be a pupil facet system. Hereinafter, however, the facet system is designated as an optical system 300A.

The optical system 300A comprises a main body or a substrate 302. The substrate 302 may comprise silicon in particular. The substrate 302 is part of the main body 224 of the field facet mirror 202 or securely connected therewith. Consequently, the substrate 302 forms a “fixed world” of the optical system 300A.

Further, the optical system 300A comprises a facet element 304, in particular a field facet element, having an optically effective surface 306. The optically effective surface 306 is a mirror surface. The optically effective surface 306 is suitable for reflecting EUV radiation 108A. The optically effective surface 306 corresponds in particular to the optically effective surface 226 in accordance with FIG. 6.

A plurality of piezoactuators 308, 310, 312, 314 connected in a row are provided between the substrate 302 and the facet element 304. The piezoactuators 308, 310, 312, 314 can also be designated as piezoelements or piezo actuating elements. All piezoactuators 308, 310, 312, 314 are arranged in a common plane E. The plane E is spanned by the x-direction x and the y-direction y, or is placed parallel to a plane spanned by the x-direction x and the y-direction y.

A principal direction of extent H is assigned to each piezoactuator 308, 310, 312, 314 but is only plotted for a first piezoactuator 308 in FIG. 7. The principal direction of extent H of the first piezoactuator 308 is oriented in the x-direction x. In the present case, the principal direction of extent H should be understood to be the direction in which the respective piezoactuator 308, 310, 312, 314 has its greatest geometric extent.

The first piezoactuator 308 is securely connected to the substrate 302 over its entire length at a linking site 316. The linking site 316 is provided on a back side 318 of the first piezoactuator 308. The other piezoactuators 310, 312, 314 have no contact with the substrate 302. A front side 320 of the first piezoactuator 308 is securely connected to a second piezoactuator 310 at an end-side connection site 322 of the latter. The second piezoactuator 310 likewise has a back side 324 and a front side 326. The front side 326 is securely connected to a third piezoactuator 312 at an end-side connection site 328 of the latter such that the second piezoactuator 310 is arranged between the first piezoactuator 308 and the third piezoactuator 312. The third piezoactuator 312 also comprises a back side 330 and a front side 332.

With the aid of an end-side connection site 334, a fourth piezoactuator 314 is connected to the front side 332 of the third piezoactuator 312. The fourth piezoactuator 314 also comprises a back side 336 and a front side 338. A connection portion 340 with a linking site 342, to which the facet element 304 is securely connected, projects from the front side 338.

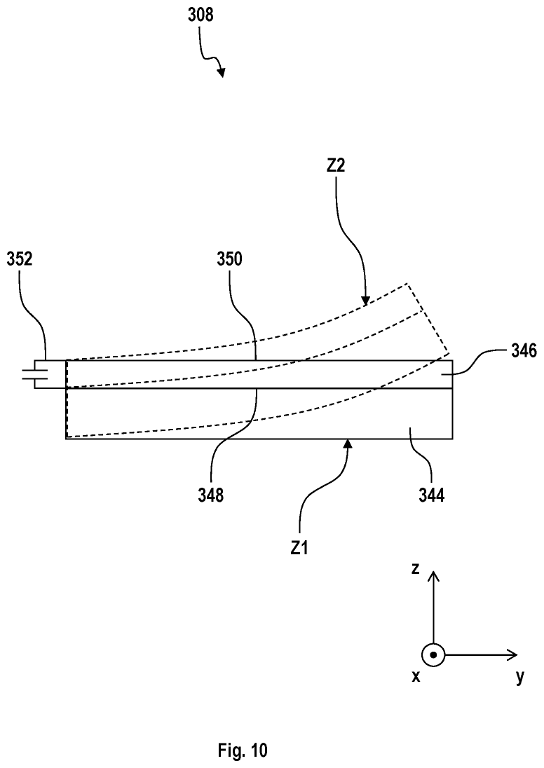

FIG. 10 shows an embodiment of the first piezoactuator 308. The piezoactuators 308, 310, 312, 314 can have an identical structure such that only the first piezoactuator 308 is discussed below. The following explanations in relation to the first piezoactuator 308 are accordingly applicable to the piezoactuators 310, 312, 314. The first piezoactuator 308 comprises a carrier layer 344. The carrier layer 344 can be manufactured from silicon, in particular from polycrystalline or monocrystalline silicon. A piezo-layer 346 is arranged on the carrier layer 344. The piezo-layer 346 may be based on piezoceramics, such as lead zirconate titanate (PZT).

The piezo-layer 346 is placed between a first electrode 348 and a second electrode 350. In this case, the first electrode 348 is arranged between the carrier layer 344 and the piezo-layer 346. The electrodes 348, 350 can be energized with the aid of a voltage source 352.

The functionality of the first piezoactuator 308 is explained below. The first piezoactuator 308 is fixed or clamped on the left-hand side in the orientation of FIG. 10. An electric field forms within the piezo-layer 346 when a voltage is applied to the piezo-layer 346 with the aid of the electrodes 348, 350. As a result, the piezo-layer 346 shrinks or contracts in a direction parallel to a layer plane presently spanned by the x-direction x and the y-direction y, as a result of which the piezo-layer 346 bends upwards in the orientation of FIG. 10, together with the carrier layer 344. The first piezoactuator 308 may also be designated as a unimorph actuator or unimorph piezoactuator.

When a voltage is applied to the first piezoactuator 308 or when the first piezoactuator 308 is actuated, the first piezoactuator 308 is brought from a non-deformed or non-deflected state Z1 (depicted using solid lines) into a deformed or deflected state Z2 (depicted using dashed lines). Any number of intermediate states may be provided between the non-deflected state Z1 and the deflected state Z2, and so the first piezoactuator 308 is continuously deflectable between the non-deflected state Z1 and the deflected state Z2. By way of example, the deflection of the first piezoactuator 308 may be implemented in voltage-dependent fashion, for example in such a way that the deflection of the first piezoactuator 308 increases when an increased voltage is applied to the electrodes 348, 350.

Returning to FIGS. 7 to 9, the functionality of the optical system 300A is now explained. With the aid of the piezoactuators 308, 312, it is possible to tilt the facet element 304 in opposite senses about the x-direction x or about an axis extending parallel to the x-direction x. By way of example, if only the first piezoactuator 308 is actuated, the facet element 304 carries out an anticlockwise tilt about the x-direction x in the orientation of FIG. 8, as indicated in FIG. 8 with the aid of a tilt movement K1.

By contrast, if only the third piezoactuator 312 is actuated, the facet element 304 carries out a clockwise tilt about the x-direction x in the orientation of FIG. 8, as indicated in FIG. 8 with the aid of a tilt movement K2. If both piezoactuators 308, 312 are actuated simultaneously and also deflected to the same extent, the facet element 304 carries out a pure stroke movement H1 in the z-direction z, without a tilt about the x-direction x. A combined movement of the facet element 304 from the tilt movements K1, K2 and the stroke movement H1 is able to be obtained by simultaneously actuating the two piezoactuators 308, 312 with an unequal deflection of same at the same time.

As shown in FIG. 9, with the aid of the piezoactuators 310, 314, it is possible to tilt the facet element 304 in opposite senses about the y-direction y or about an axis extending parallel to the y-direction y. By way of example, if only the second piezoactuator 310 is actuated, the facet element 304 carries out a clockwise tilt about the y-direction y in the orientation of FIG. 9, as indicated in FIG. 9 with the aid of a tilt movement K3.

By contrast, if only the fourth piezoactuator 314 is actuated, the facet element 304 carries out an anticlockwise tilt about the y-direction y in the orientation of FIG. 9, as indicated in FIG. 9 with the aid of a tilt movement K4. If both piezoactuators 310, 314 are actuated simultaneously and also deflected to the same extent, the facet element 304 carries out a pure stroke movement H2 in the z-direction z. A combined movement of the facet element 304 from the tilt movements K3, K4 and the stroke movement H2 is able to be obtained by simultaneously actuating the two piezoactuators 310, 314 with an unequal deflection of same at the same time.

By actuating all piezoactuators 308, 310, 312, 314 in combination, it is possible to obtain a combined tilt/stroke movement about the x-direction x, about the y-direction y and in the z-direction z. A control unit 354 is provided for actuating the piezoactuators 308, 310, 312, 314.

As a result of this sequential arrangement of the piezoactuators 308, 310, 312, 314 as explained above, it is possible to tilt the facet element 304 about two axes, specifically the x-direction x and the y-direction y, in each case in the positive and negative direction as explained on the basis of the tilt movements K1, K2, K3, K4. As a result of simultaneously operating several or all piezoactuators 308, 310, 312, 314, it is possible to realize combinations of the tilt movements K1, K2, K3, K4 about the x-direction x and the y-direction y, and so an overall two-dimensional tilt field can be set for the facet element 304.

Moreover, the drive with the aid of the piezoactuators 308, 310, 312, 314 offers the option of moving the facet element 304 in a direction orthogonal to the optically effective surface 306, specifically along the z-direction z, with the aid of the stroke movement H1, H2. By way of example, if the two piezoactuators 308, 312 or 310, 314 assigned to a direction x, y are operated simultaneously at the same voltage, there is no tilt of the facet element 304, as explained above, but instead a translation, specifically the respective stroke movement H1, H2, along the z-direction z.

The same applies to the parallel operation of all four piezoactuators 308, 310, 312, 314. Consequently, the facet element 304 has three degrees of freedom, specifically the tilt movements K1, K2, K3, K4 about the x-direction x and the y-direction y, and the stroke movement H1, H2 along the z-direction z. This property offers an additional degree of freedom and hence additional flexibility in the setting of illumination states.

The integration of a sensor system, for example in order to register the deflection of the piezoactuators 308, 310, 312, 314, can be implemented for example by way of capacitive elements, for example in the form of electrodes, or piezoresistive sensors, which for example are arranged parallel to the piezoactuators 308, 310, 312, 314. Electrodes may be attached to a top side of the piezoactuators 308, 310, 312, 314 for the purposes of realizing a capacitive sensor system. Corresponding counter electrodes can then be attached accordingly to a bottom side of the facet element 304. Then, the distances between the electrodes on the piezoactuators 308, 310, 312, 314 and the electrodes on the bottom side of the facet element 304 change when the facet element 304 tilts. Consequently, the capacitance changes as a function of a tilt angle of the facet element 304. A capacitive sensor can consequently be implemented.

When the sensor system is realized by piezoresistive sensors, a sensor 356, 358, 360, 362 is assigned to each piezoactuator 308, 310, 312, 314. By way of example, the sensors 356, 358, 360, 362 are piezoresistive elements, which change their resistance in the case of a deformation of same. The piezoresistive sensors 356, 358, 360, 362 can be integrated in movable elements, for example the carrier layer 344, or can be applied thereon at a free site. Alternatively, the piezoresistive sensors 356, 358, 360, 362 may be situated in/on an additional bending element that is parallel to the piezo-layer 346.

Together, the piezoactuators 308, 312 form a first piezoactuator arrangement 364 of the optical system 300A, which facilitate the tilt movements K1, K2 about the x-direction x. By contrast, the piezoactuators 310, 314 together form a second piezoactuator arrangement 366 of the optical system 300A, which facilitate the tilt movements K3, K4 about the y-direction y.

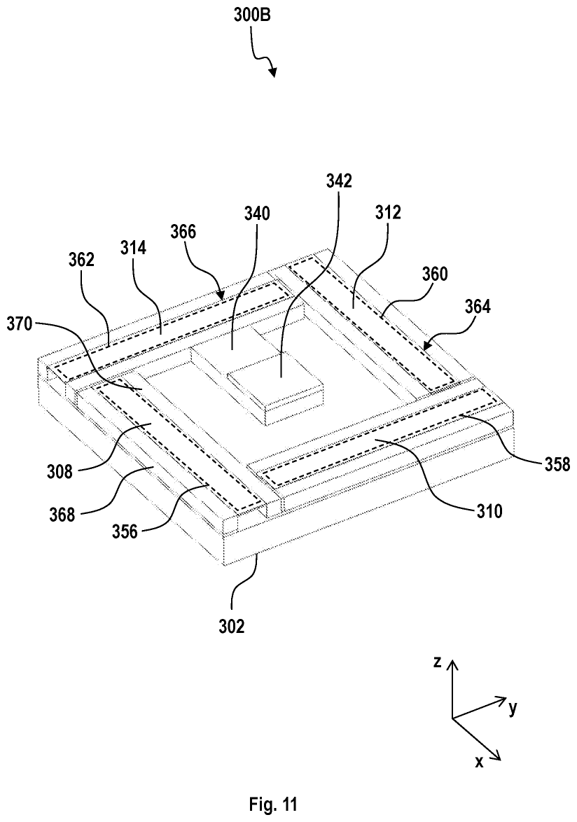

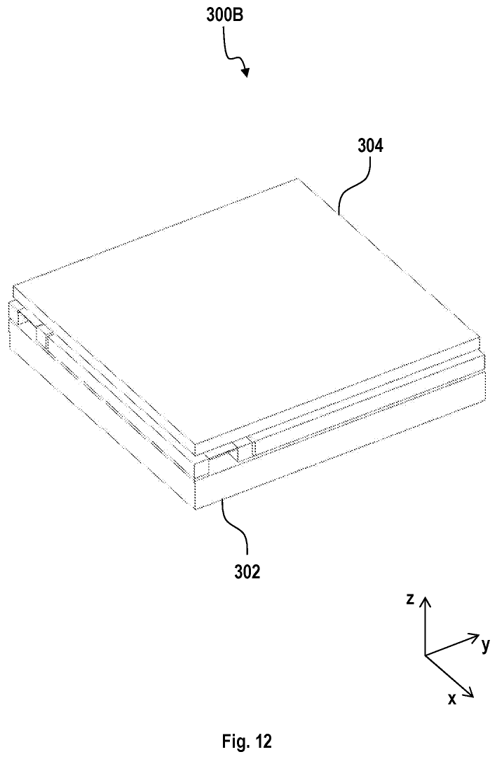

FIG. 11 and FIG. 12 each show a schematic perspective view of a further embodiment of an optical system 300B, with the facet element 304 not being depicted in FIG. 11. The optical system 300B only differs from the optical system 300A in that the optical system 300B represents a possible structural embodiment of the optical system 300A shown only very schematically in FIGS. 7 to 9.

Two strip-shaped coupling elements 368, 370, in particular a first coupling element 368 and a second coupling element 370, are assigned to each piezoactuator 308, 310, 312, 314, the respective piezoactuator 308, 310, 312, 314 being arranged between and securely connected to its assigned strip-shaped coupling elements. Only the coupling elements 368, 370 of the first piezoactuator 308 have been provided with a reference sign in FIG. 11.

The coupling elements 368, 370 may be manufactured from the same material as the substrate 302. Only the first coupling element 368 of the first piezoactuator 308 is connected securely and over its entire length to the substrate. By way of example, the first coupling element 368 of the first piezoactuator 308 is integrally connected, in particular integrally connected in terms of material, to the substrate 302.

In the present case, “integral” or “one piece” means that the substrate 302 and the first coupling element 368 of the first piezoactuator 308 form a common component and have not been assembled from different components. In the present case, “integral in terms of material” means that the first coupling element 368 of the first piezoactuator 308 and the substrate 302 are manufactured from the same material throughout. All other coupling elements 368, 370 have no connection to the substrate 302. The functionality of the optical system 300B corresponds to that of the optical system 300A.

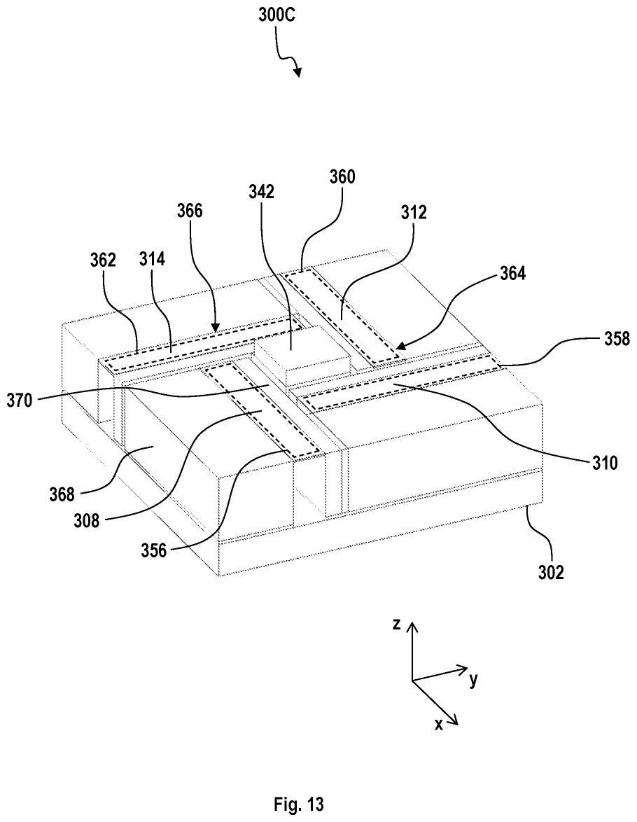

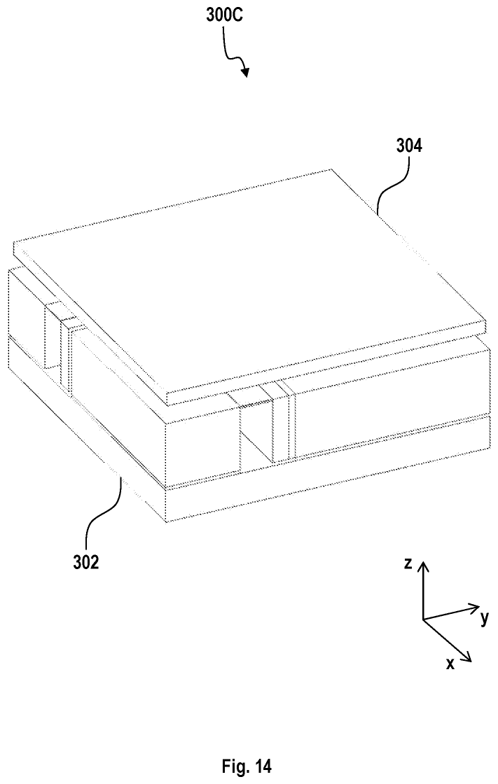

FIG. 13 and FIG. 14 each show a schematic perspective view of a further embodiment of an optical system 300C, with the facet element 304 not being depicted in FIG. 13. In terms of its structure, the optical system 300C corresponds to that of the optical system 300B, with the difference that the coupling elements 368, 370 of the optical system 300C have a larger cross-sectional area than those of the optical system 300B. The functionality of the optical systems 300B, 300C is identical.

To manage a high thermal load it is advantageous to design the piezoactuators 308, 310, 312, 314 and the connection sites 322, 328, 334 so that these, in summation, have the lowest possible thermal resistance. To this end, the cross-sectional area of the connection sites 322, 328, 334 should be chosen to be as large as possible. Moreover, wide piezoactuators 308, 310, 312, 314 are advantageous as these reduce the thermal resistance and at the same time only cause a small impairment in a maximally achievable tilt angle of the facet element 304.

The optical system 300A, 300B, 300C described can be realized using conventional microelectromechanical production methods. In this case, a three-dimensional microstructure constructed from a plurality of base layers, in particular made from silicon, is realized using different coating methods, microstructuring and etching techniques, and bonding methods.

The advantages of the optical system 300A, 300B, 300C are explained below. The piezoactuators 308, 310, 312, 314 facilitate a realization of large tilt angles. These large tilt angles can be obtained on account of using piezoactuators 308, 310, 312, 314 with a high force density and on account of the direct conversion of the bending of the piezoactuators 308, 310, 312, 314 into the respective tilt movement K1, K2, K3, K4 of the facet element 304.

The piezoactuators 308, 310, 312, 314 involve little space and hence leave a lot of space for the integration of a sensor system. By way of example, sensors may be provided for registering a position of the facet element 304. Consequently, a regulated system can be constructed. Producibility of the optical system 300A, 300B, 300C is simple since the respective design only contains a few components with a simple structure, all of which are arranged in the common plane E. It offers additional flexibility by the option of the stroke movement H1, H2 of the facet element 304.

Although the present summary has been described on the basis of exemplary embodiments, it can be modified in various ways.

### LIST OF REFERENCE SIGNS

100A EUV lithography apparatus
100B DUV lithography apparatus
102 Beam-shaping and illumination system
104 Projection system
106A EUV light source
106B DUV light source
108A EUV radiation
108B DUV radiation
110 Mirror
112 Mirror
114 Mirror
116 Mirror
118 Mirror
120 Photomask
122 Mirror
124 Wafer
126 Optical axis
128 Lens element
130 Mirror
132 Medium
200 Optical arrangement
202 Mirror/field facet mirror
204 Mirror/pupil facet mirror
206 Mirror
208 Mirror
210 Deflection mirror
212 Housing
214 Intermediate focus
216 Beam path
218 Object plane
220 Object field
222 Facet/field facet
222A Field facet
222B Field facet
222C Field facet
222D Field facet
222E Field facet
222F Field facet
224 Main body
226 Optically effective surface
228 Main body
230A Pupil facet
230B Pupil facet
230C Pupil facet
230D Pupil facet
230E Pupil facet
230F Pupil facet
232 Optically effective surface
234A Imaging light beam
234B Imaging light beam
234C Imaging light beam
300A Optical system/facet system
300B Optical system/facet system
300C Optical system/facet system
302 Substrate
304 Facet element
306 Optically effective surface
308 Piezoactuator
310 Piezoactuator
312 Piezoactuator
314 Piezoactuator
316 Linking site
318 Back side
320 Front side
322 Connection site
324 Back side
326 Front side
328 Connection site
330 Back side
332 Front side
334 Connection site
336 Back side
338 Front side
340 Connection portion
342 Linking site
344 Carrier layer
346 Piezo-layer
348 Electrode
350 Electrode
352 Voltage source
354 Control unit
356 Sensor
358 Sensor
360 Sensor
362 Sensor
364 Piezoactuator arrangement
366 Piezoactuator arrangement
368 Coupling element
370 Coupling element
400 Optical arrangement
402 Radiation source
404 Collector
406 Intermediate focal plane
408 Facet mirror
410 Specular reflector
412 Object plane
414 Object field
416 Pupil plane
E Plane
H Principal direction of extent
H1 Stroke movement
H2 Stroke movement
K1 Tilt movement
K2 Tilt movement
K3 Tilt movement
K4 Tilt movement
M1 Mirror
M2 Mirror
M3 Mirror
M4 Mirror
M5 Mirror
M6 Mirror
P1 Tilt position
P2 Tilt position
P3 Tilt position
x x-direction
y y-direction
z z-direction
Z1 State
Z2 State

What is claimed is:

1. A facet system, comprising:
a facet element comprising an optically effective surface;
a first piezoactuator arrangement configured to tilt the facet element about a first spatial direction; and
a second piezoactuator arrangement configured to tile the facet element about a second spatial direction which is perpendicular to the first spatial direction,
wherein:
the first and second piezoactuator arrangements are in a common plane spanned by the first and second spatial directions; and
at least one arrangement selected from the group consisting of the first piezoactuator arrangement and the second piezoactuator arrangement is configured to perform a stroke movement of the facet element in a third spatial direction which is perpendicular to the optically effective surface.

2. The facet system of claim 1, wherein the first piezoactuator arrangement comprises two piezoactuators configured to selectively tilt the facet element about the first spatial direction in two oppositely oriented tilt movements.

3. The facet system of claim 2, wherein the second piezoactuator arrangement comprises two piezoactuators configured to selectively tilt the facet element about the second spatial direction in two oppositely oriented tilt movements.

4. The facet system of claim 3, wherein the piezoactuators of the first piezoactuator arrangement and the piezoactuators of the second piezoactuator arrangement are in a row.

5. The facet system of claim 4, wherein the piezoactuators of the first piezoactuator arrangement and the piezoactuators of the second piezoactuator arrangement alternate.

6. The facet system of claim 5, wherein the piezoactuators of the first piezoactuator arrangement are parallel to one another and spaced apart from one another, and the piezoactuators of the second piezoactuator arrangement are parallel to one another and spaced apart from one another.

7. The facet system of claim 6, wherein the piezoactuators of the first piezoactuator arrangement are perpendicular to the piezoactuators of the second piezoactuator.

8. The facet system of claim 7, further comprising first, second, third and fourth piezoactuators, wherein the first and third piezoactuators are assigned to the first piezoactuator arrangement, and wherein the second and fourth piezoactuator are assigned to the second piezoactuator arrangement.

9. The facet system of claim 8, further comprising a substrate, wherein only the first piezoactuator is connected to the substrate.

10. The facet system of claim 9, wherein the first piezoactuator is only connected to the substrate and the second piezoactuator, the second piezoactuator is only connected to the first piezoactuator and the third piezoactuator, the third piezoactuator is only connected to the second piezoactuator and the fourth piezoactuator, and the fourth piezoactuator is only connected to the third piezoactuator and the facet element.

11. The facet system of claim 3, wherein the piezoactuators of the first piezoactuator arrangement and the piezoactuators of the second piezoactuator arrangement alternate.

12. The facet system of claim 3, wherein the piezoactuators of the first piezoactuator arrangement are parallel to one another and spaced apart from one another, and the piezoactuators of the second piezoactuator arrangement are parallel to one another and spaced apart from one another.

13. The facet system of claim 3, wherein the piezoactuators of the first piezoactuator arrangement are perpendicular to the piezoactuators of the second piezoactuator.

14. The facet system of claim 3, further comprising first, second, third and fourth piezoactuators, wherein the first and third piezoactuators are assigned to the first piezoactuator arrangement, and wherein the second and fourth piezoactuator are assigned to the second piezoactuator arrangement.

15. The facet system of claim 3, further comprising a substrate, wherein only the first piezoactuator is connected to the substrate.

16. The facet system of claim 3, wherein the first piezoactuator is only connected to the substrate and the second piezoactuator, the second piezoactuator is only connected to the first piezoactuator and the third piezoactuator, the third piezoactuator is only connected to the second piezoactuator and the fourth piezoactuator, and the fourth piezoactuator is only connected to the third piezoactuator and the facet element.

17. The facet system of claim 1, the first piezoactuator arrangement is configured to perform a stroke movement of the facet element in a third spatial direction which is perpendicular to the optically effective surface, and the second piezoactuator arrangement is configured to perform a stroke movement of the facet element in a third spatial direction which is perpendicular to the optically effective surface.

18. The facet system of claim 1, wherein the facet element is square in the plan view.

19. The facet system of claim 1, further comprising sensors.

20. An apparatus, comprising:
the facet system of claim 1,
wherein the apparatus is a lithography apparatus.
